(19) United States
(12) Patent Application Publication
(10) Pub. No.: US 2026/0026040 A1
(43) Pub. Date: Jan. 22, 2026

(54) DUAL SILICIDE SHARED SOURCE/DRAIN CONTACT

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Oleg Gluschenkov, Tannersville, NY (US)

(21) Appl. No.: 18/774,628

(22) Filed: Jul. 16, 2024

(51) Int. Cl. H01L 29/417; H01L 27/088; H01L 29/06; H01L 29/423; H01L 29/66; H01L 29/775; H01L 29/786

(52) U.S. Cl. CPC H10D 30/6729; H10D 30/014; H10D 30/43; H10D 30/6713; H10D 30/6735; H10D 30/6757; H10D 62/121; H10D 84/83

(57) ABSTRACT

Embodiments of present invention provide a semiconductor structure. The semiconductor structure includes a stack of transistors including a second transistor on top of a first transistor on a substrate, the first and the second transistor each having a first source/drain (S/D) region with the first S/D region of the second transistor being on top of the first S/D region of the first transistor; and a shared S/D contact with the shared S/D contact having a first portion being wrapped around by the first S/D region of the first transistor and a second portion being wrapped around by the first S/D region of the second transistor. A method of forming the same is also provided.

### BACKGROUND

The present application relates to manufacturing of semiconductor integrated circuits. More particularly, it relates to a method of forming shared S/D contact and the structure formed thereby.

As semiconductor industry moves towards smaller node, transistors such as nanosheet transistors are vertically stacked together to double the density of transistors. Additionally, backside power rail (BPR) and backside power distribution network (BSPDN) are being used to provide powering and/or signal routing functions to the stacked transistors from the backside of the semiconductor chip.

In an attempt to contact source/drain regions of both the bottom and the top transistor in a stacked transistor structure, it is conventional to first form an opening to reach the source/drain regions of both the bottom and the top transistors, and then filling the opening with a conductive material to form a contacting via contacting the source/drain regions of both transistors. However, the opening so formed usually has a high-aspect ratio, which may cause process complexity such as, for example causing complete epi etch-out if the process is not managed properly.

### SUMMARY

Embodiments of present invention provide a semiconductor structure. The semiconductor structure includes a stack of transistors including a second transistor on top of a first transistor, the first and the second transistor each having a first and a second source/drain (S/D) region, the first S/D region of the second transistor being on top of the first S/D region of the first transistor and the second S/D region of the second transistor being on top of the second S/D region of the first transistor; and a shared S/D contact, the shared S/D contact having a first portion being wrapped around by the first S/D region of the first transistor and a second portion being wrapped around by the first S/D region of the second transistor.

In one embodiment, the first S/D region of the first transistor includes a first type of silicide that surrounds the first portion of the shared S/D contact, and the first S/D region of the second transistor includes a second type of silicide that surrounds the second portion of the shared S/D contact, the first type of silicide being materially different from the second type of silicide.

In another embodiment, the first transistor is an n-type nanosheet transistor and the second transistor is a p-type nanosheet transistor, and the first type of silicide is a titanium-silicide and the second type of silicide is a nickel-platinum-silicide.

In yet another embodiment, at least a portion of a top surface of the first S/D region of the first transistor is covered by the second type of silicide.

In one embodiment, the first portion of the shared S/D contact has a top cross-section and a bottom cross-section with the top cross-section being closer to the second portion of the shared S/D contact than the bottom cross-section and having a smaller cross-sectional area than the bottom cross-section; and the second portion of the shared S/D contact has a top cross-section and a bottom cross-section with the bottom cross-section being closer to the first portion of the shared S/D contact than the top cross-section and having a smaller cross-sectional area than the top cross-section.

In another embodiment, the top cross-section of the first portion of the shared S/D contact and the bottom cross-section of the second portion of the shared S/D contact have different cross-sectional shapes and sizes.

According to one embodiment, the semiconductor structure further includes a bottom S/D contact being wrapped around by the second S/D region of the first transistor and a top S/D contact being wrapped around by the second S/D region of the second transistor, where the bottom S/D contact is isolated from the top S/D contact by a middle-dielectric-insulator layer.

According to another embodiment, the semiconductor structure further includes a middle-dielectric-insulator layer, the middle-dielectric-insulator layer surrounding a section of the shared S/D contact; being above the first S/D region of the first transistor; and being below the first S/D region of the second transistor.

In one embodiment, the first portion of the shared S/D contact has a first sidewall leaning inwardly, and the second portion of the shared S/D contact has a second sidewall leaning outwardly.

Embodiments of present invention further provide a method of forming a semiconductor structure. The method includes forming a stack of transistors on a substrate, the stack of transistors including a second transistor on top of a first transistor, the first and the second transistor each having a first and a second source/drain (S/D) region, the first S/D region of the second transistor being on top of the first S/D region of the first transistor and the second S/D region of the second transistor being on top of the second S/D region of the first transistor; creating a second opening through the first S/D region of the second transistor, the second opening exposing a top surface of the first S/D region of the first transistor; forming a second type of silicide from the first S/D region of the second transistor at the second opening; filling the second opening with a second conductive material to form a second portion of a shared S/D contact; creating a first opening through the first S/D region of the first transistor, the first opening exposing a bottom cross-section of the second portion of the shared S/D contact; forming a first type of silicide from the first S/D region of the first transistor at the first opening; and filling the first opening with a first conductive material to form a first portion of the shared S/D contact, wherein the first and the second portion of the shared S/D contact are in contact with each other and together form the shared S/D contact.

In one embodiment, creating the second opening includes creating the second opening through a selective etch process from a frontside of the substrate resulting the second portion of the shared S/D contact having a top cross-section and a bottom cross-section with the bottom cross-section being closer to the first portion of the shared S/D contact than the top cross-section and having a smaller cross-sectional area than the top cross-section.

In another embodiment, creating the first opening includes creating the first opening through a selective etch process from a backside of the substrate resulting the first portion of the shared S/D contact having a top cross-section and a bottom cross-section with the top cross-section being closer to the second portion of the shared S/D contact than the bottom cross-section and having a smaller cross-sectional area than the bottom cross-section.

In yet another embodiment, forming the second type of silicide further includes forming the second type of silicide at the top surface of the first S/D region of the first transistor exposed by the second opening.

In one embodiment, creating the first opening includes removing at least a portion of the second type of silicide formed at the top surface of the first S/D region of the first transistor to expose a bottom cross-section of the second portion of the shared S/D contact.

In another embodiment, creating the first opening further includes selectively removing a placeholder underneath the first S/D region of the first transistor to expose the first S/D region of the first transistor.

According to one embodiment, the method further includes creating a third opening through the second S/D region of the second transistor to expose a middle-dielectric-insulator layer that isolates the second S/D region of the second transistor from the second S/D region of the first transistor, and filling the third opening with a conductive material to form a top S/D contact being wrapped around by the second S/D region of the second transistor.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B to FIGS. 11A and 11B are demonstrative illustrations of cross-sectional views and FIG. 1C to FIG. 11C are simplified top views of a semiconductor structure at various steps of manufacturing thereof according to embodiments of present invention; and

FIG. 12 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the case of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

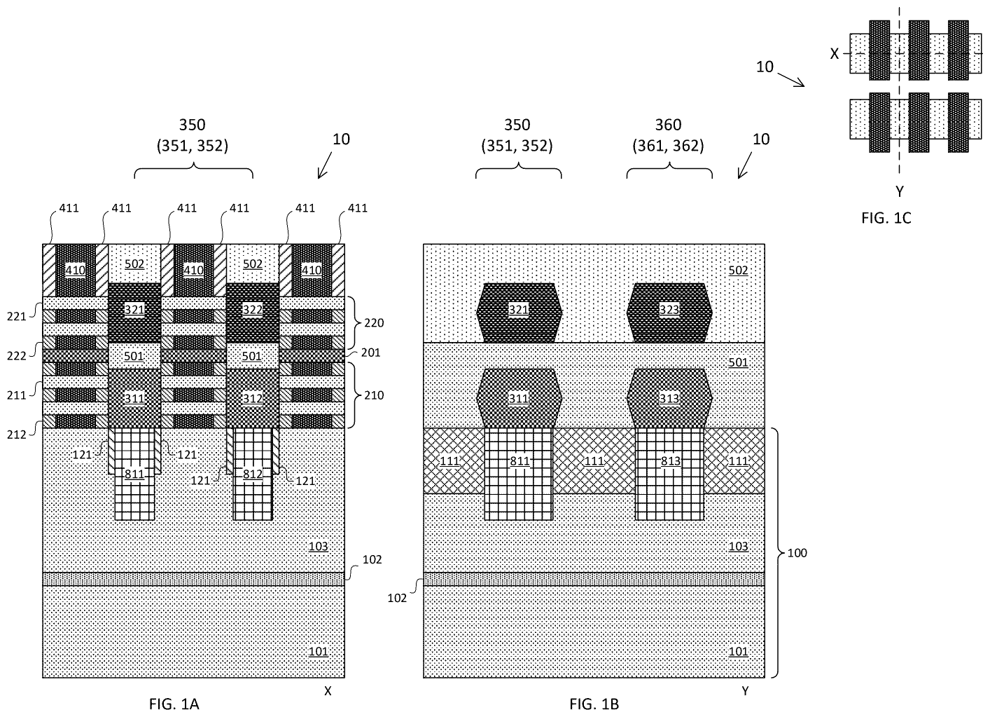

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of a semiconductor structure 10 with a cross-section made along a dashed line X as illustrated in FIG. 1C. In other words, the cross-section in FIG. 1A is made across the gate in a direction along the length of the gate. FIG. 1B illustrates a cross-sectional view of the semiconductor structure with a cross-section made along a dashed line Y as illustrated in FIG. 1C. In other words, the cross-section in FIG. 1B is made across the S/D region in a direction along the width of the gate. As its purpose is to illustrate locations of the cross-sections illustrated in FIGS. 1A and 1B, the simplified top view of FIG. 1C may selectively illustrate only key elements such as, for example, nanosheets, gates, S/D regions that are formed, previously formed, or yet to be formed or whose views may sometimes be obstructed. Other elements such as dielectric cap layer, sidewall spacers, etc. may not necessarily be illustrated in order not to overcrowd FIG. 1C, and to the extent that their omission from FIG. 1C does not hinder the description of embodiments of present invention, which are mainly provided hereinafter with reference to FIGS. 1A and 1B.

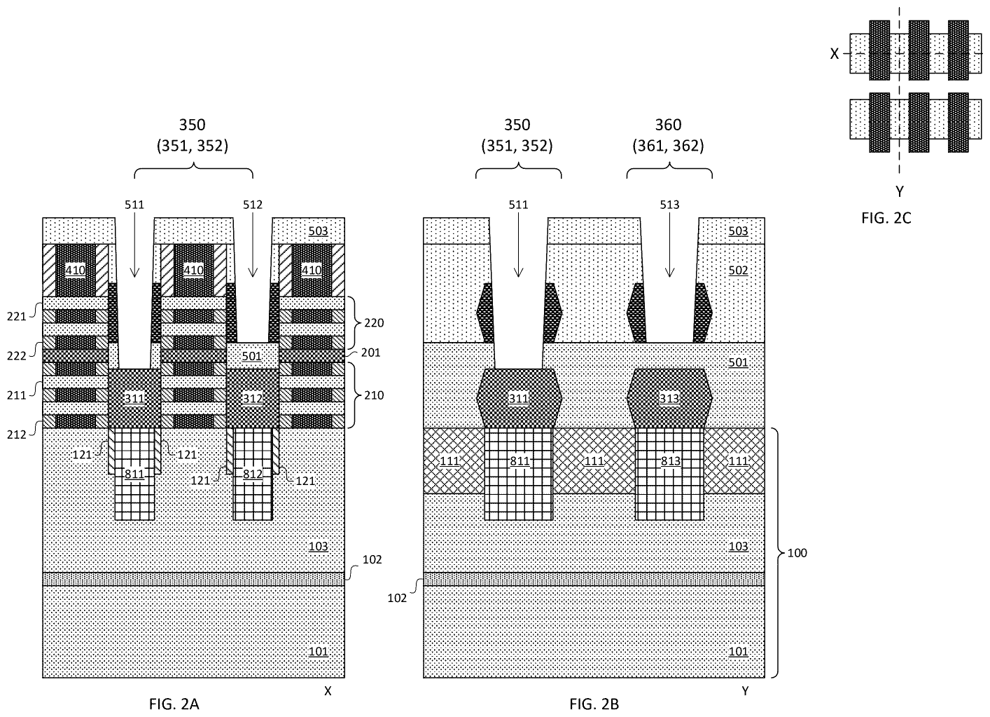

Likewise, FIGS. 2A and 2B to FIGS. 11A and 11B are demonstrative cross-sectional views and FIG. 2C to FIG. 11C are simplified top views of the semiconductor structure, at various manufacturing steps or for different embodiments, illustrated in manners similar to FIGS. 1A, 1B, and 1C respectively.

Embodiments of present invention provide forming the semiconductor structure 10 by first receiving or providing a semiconductor substrate 100. The semiconductor substrate 100 may include a bulk silicon (Si) substrate 101, an etch-stop layer (ESL) 102 on top of the Si substrate 101, and a Si layer 103 on top of the ESL 102. In one embodiment, the ESL 102 may be a layer of silicon-germanium (SiGe) containing a certain percentage of germanium (Ge) such as, for example, 25 at. % and a layer of such composition is generally referred to as a SiGe25 layer. In other words, the ESL 102 may be a SiGe25 layer. In another embodiment, the semiconductor substrate 100 may be a silicon-on-insulator (SOI) substrate with an insulating layer of, for example, silicon-oxide (SiO₂) or silicon-nitride (SiN) between a bulk substrate and a Si layer. This insulating layer may work or function as an ESL as well.

Embodiments of present invention provide further forming one or more shallow-trench-isolation (STI) structures 111 in the Si layer 103; and one or more placeholders 811, 812, and 813 of, for example, dielectric material such as SiO₂ or SiN in the Si layer 103. The one or more placeholders 811, 812, and 813 may be at least partially surrounded by the STI structures 111. Protective liners 121 may be formed at sidewalls of the placeholders 811, 812, and 813.

Embodiments of present invention further provide forming one or more stacks of nanosheet (NS) transistors on top of the semiconductor substrate 100 such as a first stack of NS transistors 350 and a second stack of NS transistors 360. However, embodiments of present invention are not limited in this aspect and may be applied to other types of transistors. The first stack of NS transistors 350 may include a bottom NS transistor 351 and a top NS transistor 352; and the second stack of NS transistors 360 may include a bottom NS transistor 361 and a top NS transistor 362. The bottom NS transistors 351 and 361 may be embedded in a bottom interlevel-dielectric (ILD) layer 501 and the top NS transistors 352 and 362 may be embedded in a top ILD layer 502. The bottom ILD layer 501 and the top ILD layer 502 may include dielectric material such as, for example, SiO₂, SiN, silicon-carbide (SiC), silicon-oxycarbide (SiOC), silicon-oxycarbonitride (SiOCN), silicon-boron-carbonitride (SiBCN), or other suitable materials. In one embodiment, the bottom ILD layer 501 and the top ILD layer 502 may include a same dielectric material. In another embodiment, the bottom ILD layer 501 and the top ILD layer 502 may include different dielectric materials.

Each NS transistor may include a set of nanosheets such as a first set of nanosheets 210 for the bottom NS transistors 351 and 361 or a second set of nanosheets 220 for the top NS transistors 352 and 362. The first set of nanosheets 210 may be insulated from the second set of nanosheets 220 by a self-aligned middle isolation (SAMI) layer 201. The SAMI layer 201 may include dielectric materials such as SiO₂, SiN, SiC, SiOC, SiOCN, SiBCN, or other dielectric materials, which may be same or different from the first and the second ILD layer 501 and 502. The first set of nanosheets 210 may include a first set of channel sheets 211 and the second set of nanosheets 220 may include a second set of channel sheets 221. The first and the second set of channel sheets 211 and 221 may each be a set of Si sheets. One or more metal gates 410 may be formed to surround the first set of channel sheets 211 and/or the second set of channel sheets 221. The one or more metal gates 410 may include a gate dielectric surrounding the first and the second set of channel sheets 211 and 221, one or more work-function-metal layers on top of the gate dielectric, and one or more gate metals on top of the one or more work-function-metal layers.

Source/drain regions of the NS transistors may be formed, for example through an epitaxial growing process, at end surfaces of the first set of channel sheets 211 of the first set of nanosheets 210, and/or the second set of channel sheets 221 of the second set of nanosheets 220. For example, bottom source/drain (S/D) regions 311 and 312 may be formed at end surfaces of the first set of channel sheets 211 of the bottom NS transistor 351. Similarly, top S/D regions 321 and 322 may be formed at end surfaces of the second set of channel sheets 221 of the top NS transistor 352. Additional S/D regions such as, for example, a bottom S/D region 313 and a top S/D region 323 may be formed for the bottom NS transistor 361 and the top NS transistor 362 respectively. The bottom S/D regions 311, 312, and 313 may be covered by the ILD layer 501 and the top S/D regions 321, 322, and 323 may be covered by the ILD layer 502. The ILD layer 501 between the top S/D region 321 and the bottom S/D region 311, and between the top S/D region 322 and the bottom S/D region 312, may be known and referred to hereafter as a middle-dielectric-insulator (MDI) layer. The MDI layer may be formed from a dielectric material that is the same as, or different from, that of the first ILD layer 501.

S/D regions of the NS transistors may be separated and/or insulated from the metal gate by inner spacers and/or sidewall spacers of the metal gate. For example, bottom S/D regions 311 and 312 of the bottom NS transistor 351 may be separated and/or insulated from the metal gate 410 by a plurality of inner spacers 212 and top S/D regions 321 and 322 of the top NS transistor 352 may be separated and/or insulated from the metal gate 410 by a plurality of inner spacers 222 and by sidewall spacers 411 at sidewalls of the metal gate 410.

FIGS. 2A and 2B are demonstrative illustrations of different cross-sectional views and FIG. 2C is a simplified top view of a semiconductor structure in a step of manufacturing thereof, according to one embodiment of present invention. More particularly, following the step illustrated in FIGS. 1A, 1B, and 1C, embodiments of present invention provide depositing dielectric material on top of the second ILD layer 502 to form an additional ILD layer 503 covering the one or more metal gates 410 of the NS transistors. The ILD layer 503 may include SiO₂, SiN, SiC, SiOC, SiOCN, SiBCN, or other suitable material, and may be formed through, for example, a chemical-vapor-deposition (CVD) process, a physical-vapor-deposition (PVD) process, or an atomic-layer-deposition (ALD) process.

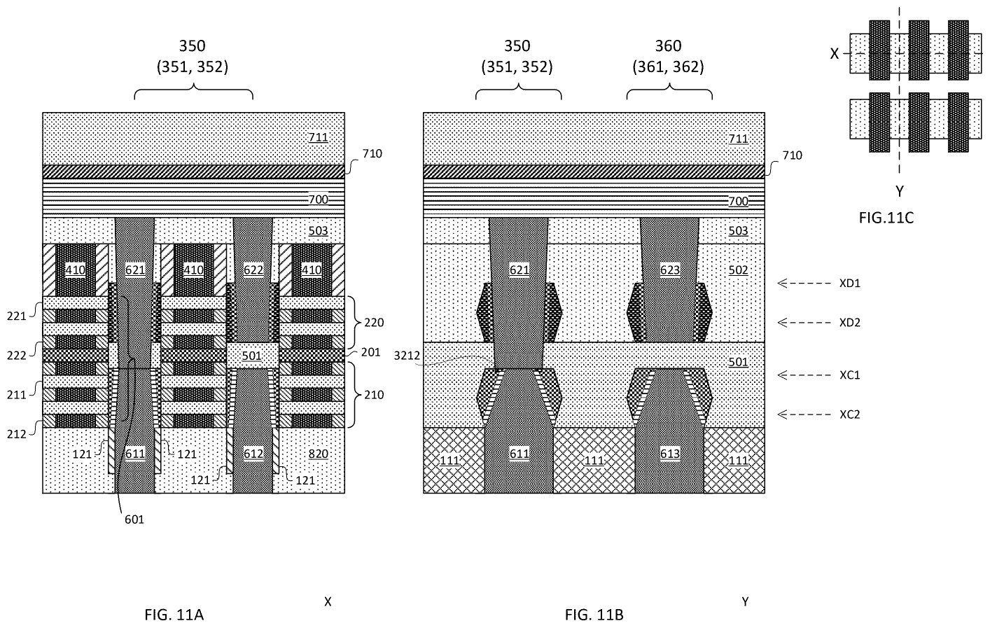

Next, one or more openings may be created, from a frontside of the semiconductor structure 10 or the semiconductor substrate 100, in the top S/D regions of the top NS transistors to form either a top portion of a shared S/D contact or a top S/D contact. For example, an opening 511 may be created through, for example, a lithographic patterning and etch process. The opening 511 may be etched to go through the ILD layers 503 and 502, go through the top S/D region 321 of the top NS transistor 352, and go through the MDI layer 501 between the top S/D region 321 and the bottom S/D region 311 of the bottom NS transistor 351 until the bottom S/D region 311 is exposed. The opening 511 may be created as part of a process to form a top portion of a shared S/D contact 601 (see FIG. 11A) that is shared by the top NS transistor 352 and the bottom NS transistor 351.

Embodiments of present invention further provide forming additional openings such as openings 512 and 513 to form one or more top S/D contacts for the one or more top NS transistors. For example, the opening 512 may be created to go through the top S/D region 322 of the top NS transistor 352 and the opening 513 may be created to go through the top S/D region 323 of the top NS transistor 362. The openings 512 and 513 may be created through a lithographic patterning and etch process and may expose a top surface of the MDI layer 501.

The openings 511, 512, and 513 may have a first horizontal cross-section and a second horizontal cross-section with the first horizontal cross-section being closer to the bottom S/D regions 311, 312, and 313 than the second horizontal cross-section. By the nature of the etch process, the first horizontal cross-section may have a cross-sectional area that is smaller than that of the second horizontal cross-section. In other words, the openings 511, 512, and 513 may have sidewalls that lean outwardly.

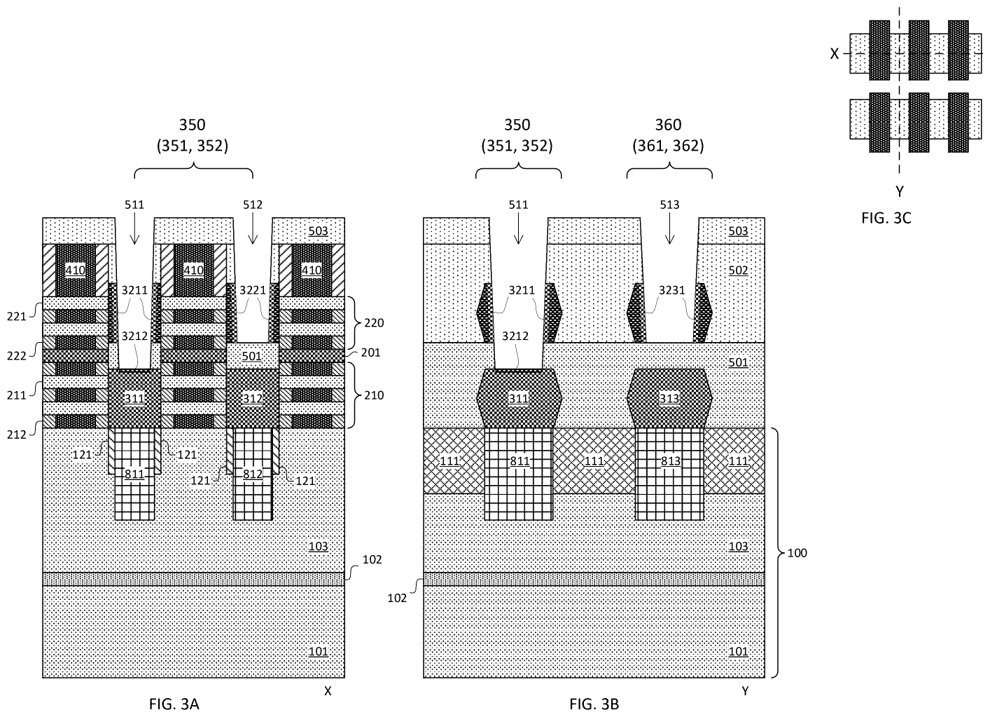

FIGS. 3A and 3B are demonstrative illustrations of different cross-sectional views and FIG. 3C is a simplified top view of a semiconductor structure in a step of manufacturing thereof, according to one embodiment of present invention. More particularly, following the step illustrated in FIGS. 2A, 2B, and 2C, embodiments of present invention provide performing a salicide process to form silicide at inner sidewalls of the openings made in the top S/D regions. For example, a silicide 3211 may be formed at inner sidewall of the opening 511 made in the top S/D region 321, a silicide 3221 may be formed at inner sidewall of the opening 512 made in the top S/D region 322, and a silicide 3231 may be formed at inner sidewall of the opening 513 made in the top S/D region 323.

In one embodiment, the top NS transistors 352 and 362 may be p-type NS transistors and the silicide 3211, 3221, and 3231 may be a p-type silicide (a second type of silicide) that is more preferable or suitable for p-type field-effect-transistors (FETs) such as p-type NS transistors. For example, the silicide 3211, 3221, and 3231 may be nickel-platinum-silicide (NiPtSix) where x represents a numerical number. However, it is to be noted here that embodiments of present invention are not limited in this aspect. The top NS transistors may be n-type NS transistors and if being n-type NS transistors the silicide 3211, 3221, and 3231 may be an n-type silicide (a first type of silicide), such as titanium-silicide (TiSix), that is more preferable or suitable for n-type NS transistors.

In one embodiment, when forming p-type silicide at inner sidewalls of the openings made in the top S/D regions of the top NS transistors, the p-type silicide may be formed at a top surface of the bottom S/D region of the bottom NS transistors that may be n-type NS transistors. For example, a silicide 3212, which may be a p-type silicide of NiPtSix, may be formed at a top surface of the bottom S/D region 311, which may be an n-type S/D region, of the bottom NS transistor 351.

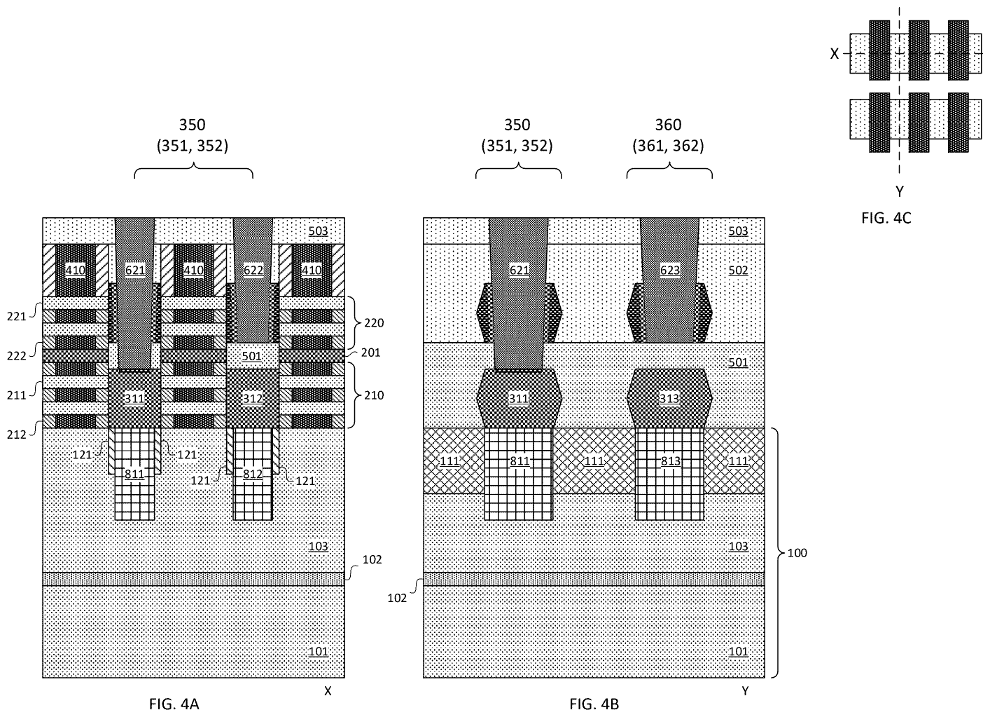

FIGS. 4A and 4B are demonstrative illustrations of different cross-sectional views and FIG. 4C is a simplified top view of a semiconductor structure in a step of manufacturing thereof, according to one embodiment of present invention. More particularly, following the step illustrated in FIGS. 3A, 3B, and 3C, embodiments of present invention provide filling the openings 511, 512, and 513 with a conductive material to form top portions of one or more shared S/D contacts such as a top portion 621 of the shared S/D contact 601, and one or more non-shared top S/D contacts such as top S/D contacts 622 and 623. The top portion 621 of the shared S/D contact 601 may be surrounded by, at least partially, and contacts the silicide 3211 and may be formed directly on top of the silicide 3212. In other words, at least a portion of the top portion 621 of the shared S/D contact 601 may be wrapped around by the top S/D region 321 and more particularly wrapped around by the silicide 3211 formed at the inner sidewall of the top S/D region 321. Similarly, at least a portion of the top S/D contacts 622 and 623 may be wrapped around by the top S/D regions 322 and 323 respectively and more particularly wrapped around by the silicide 3221 and 3231 formed at the inner sidewalls of the top S/D regions 322 and 323 respectively. In one embodiment, the conductive material forming the shared top S/D contact 601 and/or the non-shared top S/D contacts 622 and 623 may include, for example, copper (Cu), aluminum (Al), cobalt (Co), ruthenium (Ru), tungsten (W) or other suitable contact metals.

After filling the openings 511, 512, and 513 with the conductive material, a chemical-mechanical-polishing (CMP) process may be applied to planarize a top surface of the shared top S/D contact 601 and/or non-shared top S/D contacts 622 and 623. The top surface of the shared top S/D contact 601 and/or the non-shared top S/D contacts 622 and 623 may be made coplanar with the top surface of the ILD layer 503.

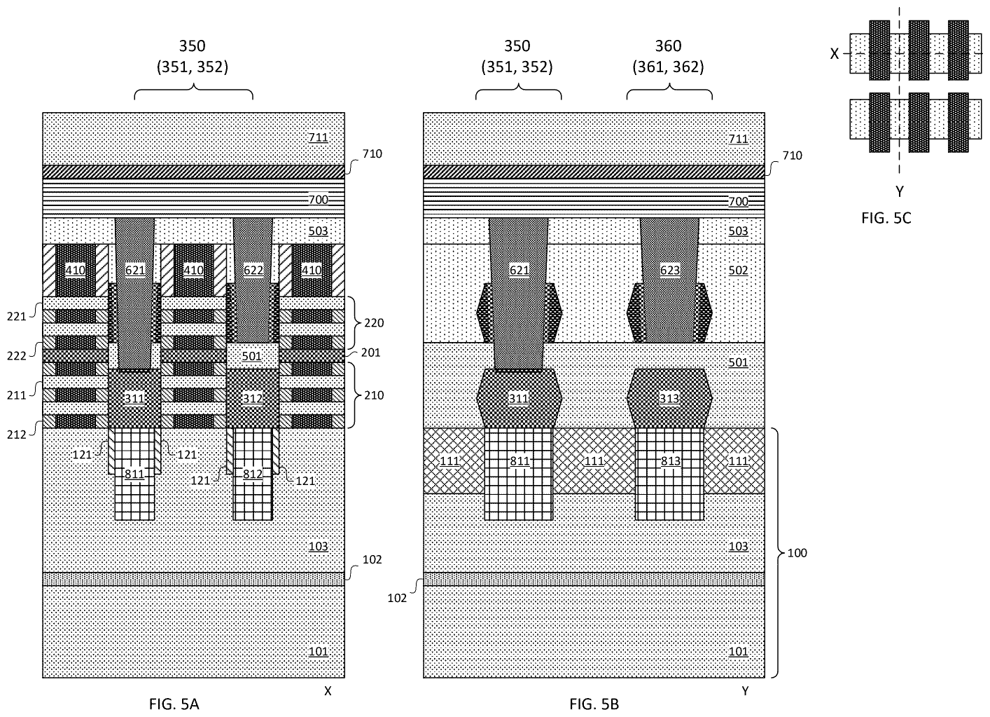

FIGS. 5A and 5B are demonstrative illustrations of different cross-sectional views and FIG. 5C is a simplified top view of a semiconductor structure in a step of manufacturing thereof, according to one embodiment of present invention. More particularly, following the step illustrated in FIGS. 4A, 4B, and 4C, embodiments of present invention provide forming a back-end-of-line (BEOL) structure 700 on top of the ILD layer 503. The BEOL structure 700 may include one or more metal levels in contact with the one or more top S/D contacts, shared or non-shared, in providing power supply and/or signal routing functions to the one or more stacks of NS transistors. For example, the BEOL structure 700 may be in contact with the top portion 621 of the shared S/D contact 601 and the top S/D contacts 622 and 623.

Next, embodiments of present invention provide attaching a handle wafer 711 to the semiconductor structure 10 such as to the BEOL structure 700. The attachment may be made through a bonding agent 710. After bonding the handle wafer 711, the semiconductor structure 10 may be flipped upside-down for further processing from a backside of the semiconductor substrate 100, as being described below in more details. Hereinafter, although the processing is made from the backside of the semiconductor substrate 100 and thus described in a manner in accordance with the upside-down structure, the final resulting structure will be described in a manner consistent with when the structure stays upside-up.

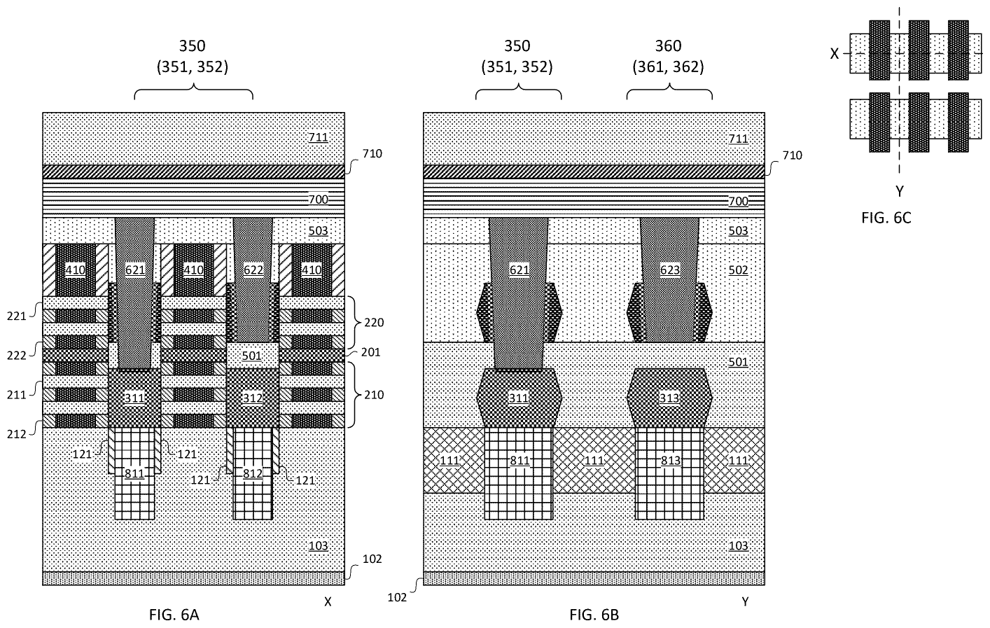

FIGS. 6A and 6B are demonstrative illustrations of different cross-sectional views and FIG. 6C is a simplified top view of a semiconductor structure in a step of manufacturing thereof, according to one embodiment of present invention. More particularly, following the step illustrated in FIGS. 5A, 5B, and 5C, embodiments of present invention provide removing the bulk Si substrate 101 of the semiconductor substrate 100 from a backside of the semiconductor structure 10. The bulk Si substrate 101 may be removed selectively through, for example, a CMP process, a grinding process, an ash process, or a combination thereof. The existence of the ESL 102 helps the removal process of the bulk Si substrate 101 such that the process may stop when the ESL 102 is reached or exposed.

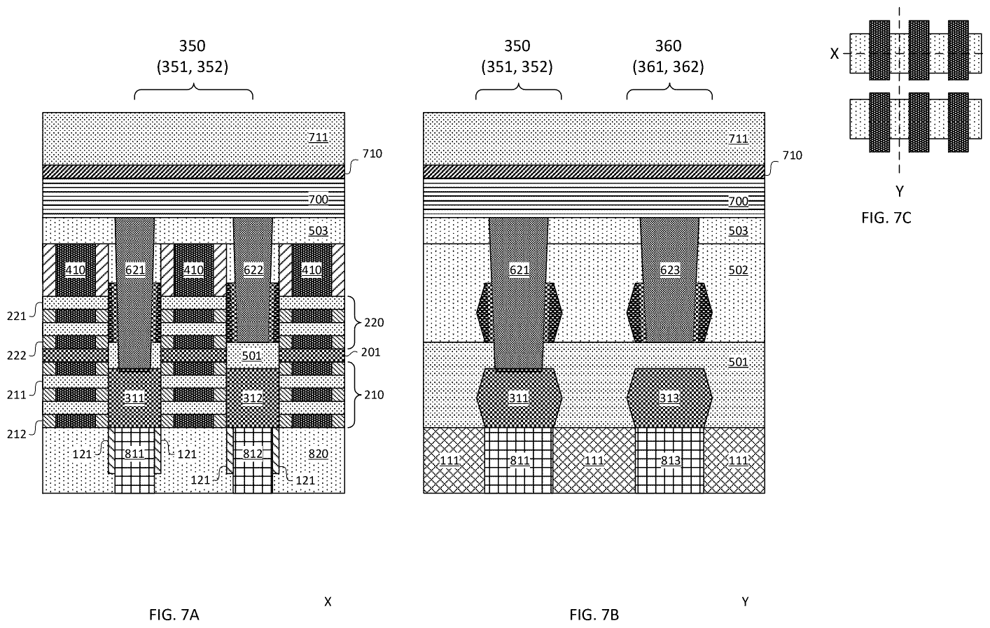

FIGS. 7A and 7B are demonstrative illustrations of different cross-sectional views and FIG. 7C is a simplified top view of a semiconductor structure in a step of manufacturing thereof, according to one embodiment of present invention. More particularly, following the step illustrated in FIGS. 6A, 6B, and 6C, embodiments of present invention provide selectively removing the ESL 102 to expose the underneath Si layer 103, which, as is illustrated in FIGS. 6A and 6B, is above the ESL 102. Subsequently, the Si layer 103 may be removed, selective to the one or more placeholders 811, 812, and 813 embedded therein, to the STI structures 111, and to the protective liner 121. After removing the Si layer 103, a backside ILD (BILD) layer 820 may be formed, for example through a deposition process, which may include a CVD process, a PVD process, or an ALD process, to cover the placeholders 811, 812, 813 and the STI structures 111. After deposition, the BILD layer 820 may be planarized through, for example, a CMP process until the placeholders 811, 812, and 813 are exposed.

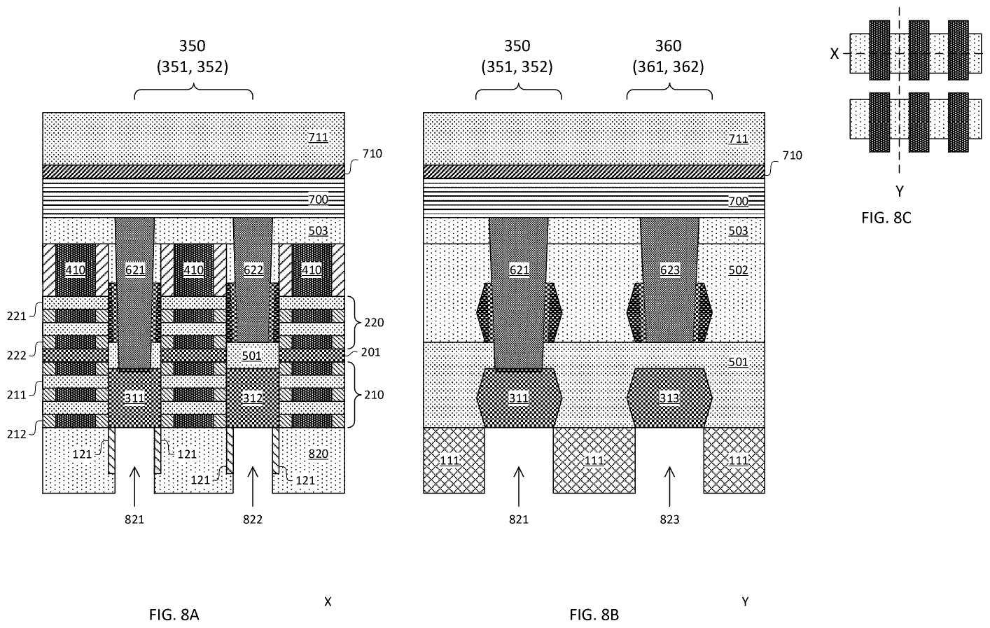

FIGS. 8A and 8B are demonstrative illustrations of different cross-sectional views and FIG. 8C is a simplified top view of a semiconductor structure in a step of manufacturing thereof, according to one embodiment of present invention. More particularly, following the step illustrated in FIGS. 7A, 7B, and 7C, embodiments of present invention provide removing the placeholders 811, 812, and 813 through a selective etch process such as a reactive-ion-etch (RIE) process, selective to the surrounding materials including the STI structures 111 and the protective liner 121. The removal of the placeholders 811, 812, and 813 may thereby create one or more openings such as openings 821, 822, and 823 that expose bottom surfaces of the bottom S/D regions of the bottom NS transistors. For example, the openings 821 and 822 may expose bottom surfaces of the bottom S/D regions 311 and 312 of the bottom NS transistor 351, and the opening 823 may expose a bottom surface of the bottom S/D region 313 of the bottom NS transistor 361.

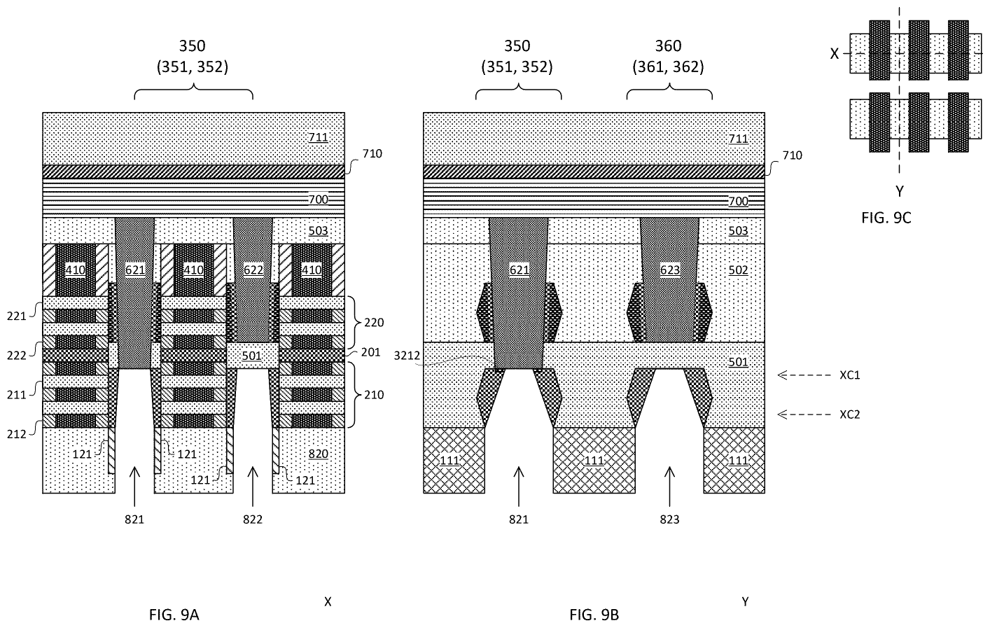

FIGS. 9A and 9B are demonstrative illustrations of different cross-sectional views and FIG. 9C is a simplified top view of a semiconductor structure in a step of manufacturing thereof, according to one embodiment of present invention. More particularly, following the step illustrated in FIGS. 8A, 8B, and 8C, embodiments of present invention provide creating openings in the exposed bottom S/D regions of the one or more bottom NS transistors in a directional and/or anisotropic etch process. More particularly, the etch process may extend the opening 821 into the bottom S/D region 311, remove at least a portion of the silicide formed at the top surface of the bottom S/D region 311 and expose a bottom surface of the top portion of the shared S/D contact. The etch process may also extend the opening 822 into the bottom S/D region 312 and extend the opening 823 into the bottom S/D region 313 until the MDI layer 501 underneath thereof is exposed. The MDI layer 501 separates and thereby insulates the top S/D contacts 622 and 623 from the bottom S/D contacts to be formed in the openings 822 and 823. The openings 821, 822, and 823 may have a first horizontal cross-section XC1 and a second horizontal cross-section XC2 with the first horizontal cross-section being closer to the bottom surface of the top portion 621 of the shared S/D contact or the MDI layer 501 than the second horizontal cross-section, which is further away from the bottom surface of the top portion 621 of the shared S/D contact or the MDI layer 501 than the first cross-section. By the nature of the etch process, the first cross-section XC1 may have a cross-sectional area that is smaller than a cross-sectional area of the second cross-section XC2.

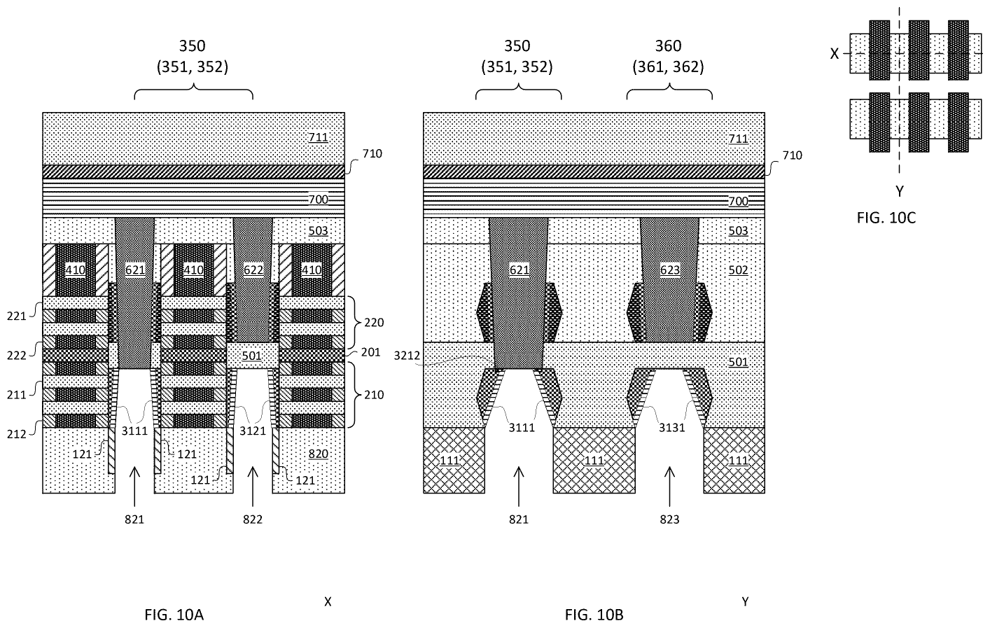

FIGS. 10A and 10B are demonstrative illustrations of different cross-sectional views and FIG. 10C is a simplified top view of a semiconductor structure in a step of manufacturing thereof, according to one embodiment of present invention. More particularly, following the step illustrated in FIGS. 9A, 9B, and 9C, embodiments of present invention provide performing a salicide process to form silicide at inner sidewalls of the openings made in the bottom S/D regions. For example, a silicide 3111 may be formed at inner sidewall of the opening 821 made in the bottom S/D region 311, a silicide 3121 may be formed at inner sidewall of the opening 822 made in the bottom S/D region 312, and a silicide 3131 may be formed at inner sidewall of the opening 823 made in the bottom S/D region 313.

In one embodiment, the bottom NS transistors 351 and 361 may be n-type NS transistors and the silicide 3111, 3121, and 3131 may be an n-type silicide that is more preferable or suitable for n-type field-effect-transistors (FETs) such as n-type NS transistors. For example, the silicide 3111, 3121, and 3131 may be titanium-silicide (TiSix) with x representing a numerical number. However, it is to be noted here that embodiments of present invention are not limited in this aspect. The bottom NS transistors may be p-type NS transistors and if being p-type NS transistors the silicide 3111, 3121, and 3131 may be a p-type silicide, such as nickel-platinum-silicide (NiPtSix) with x representing a numerical number, which is more preferable or suitable for p-type NS transistors.

FIGS. 11A and 11B are demonstrative illustrations of different cross-sectional views and FIG. 11C is a simplified top view of a semiconductor structure in a step of manufacturing thereof, according to one embodiment of present invention. More particularly, following the step illustrated in FIGS. 10A, 10B, and 10C, embodiments of present invention provide filling the openings 821, 822, and 823 with a conductive material to form one or more bottom portions of shared S/D contacts such as a bottom portion 611 of a shared S/D contact 601, and one or more bottom S/D contacts such as bottom S/D contacts 612 and 613. The bottom portion 611 of the shared S/D contact 601 may be surrounded by and contacts the silicide 3111. In other words, at least a portion of the bottom portion 611 of the shared S/D contact 601 may be wrapped around by the bottom S/D region 311 and more particularly wrapped around by the silicide 3111 formed at the inner sidewall of the bottom S/D region 311. Similarly, the bottom S/D contacts 612 and 613 may be wrapped around by the bottom S/D regions 312 and 313 respectively and more particularly wrapped around by the silicide 3121 and 3131 formed at the inner sidewalls of the bottom S/D regions 312 and 313 respectively.

The bottom portion 611 of the shared S/D contact 601 may be formed to be in direct contact with a bottom surface of the top portion 621 of the shared S/D contact 601, thereby together forming the shared S/D contact 601. In the meantime, some portions of the silicide 3212 may remain at the top surface of the bottom S/D region 312, as is demonstratively illustrated in FIG. 11B. In one embodiment, the conductive material may include, for example, Cu, Al, Co, Ru, W, or other suitable contact metals.

In one embodiment, by the nature of process as being described above, the top portion 621 of the shared S/D contact 601 may have a sidewall that leans in a first direction and the bottom portion 611 of the shared S/D contact 601 may have a sidewall that leans in a second direction that is different from the first direction. More particularly, a sidewall of the top portion 621 of the shared S/D contact 601 may lean outwardly and a sidewall of the bottom portion 611 of the shared S/D contact 601 may lean inwardly. In another embodiment, a top surface or top cross-section of the bottom portion 611 of the shared S/D contact 601 and a bottom surface of bottom cross-section of the top portion 621 of the shared S/D contact 601 may have different cross-sectional shape and size.

In one embodiment, the bottom portion 611 of the shared S/D contact 601 may have a first horizontal cross-section XC1 and a second horizontal cross-section XC2 with the first horizontal cross-section XC1 being closer to the top portion 621 of the shared S/D contact 601 than the second horizontal cross-section XC2 and having a smaller cross-sectional area than the second horizontal cross-section XC2. On the other hand, the top portion 621 of the shared S/D contact 601 may have a first horizontal cross-section XD1 and a second horizontal cross-section XD2 with the second horizontal cross-section XD2 being closer to the bottom portion 611 of the shared S/D contact 601 than the first horizontal cross-section XD1 and having a cross-sectional area smaller than a cross-sectional area of the first horizontal cross-section XD1.

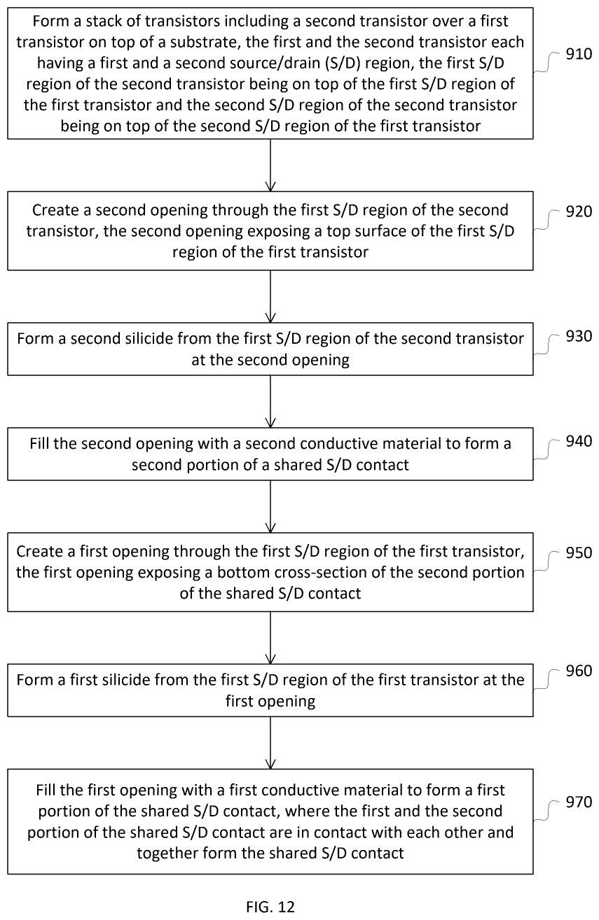

FIG. 12 is a demonstrative illustration of a flow-chart of a method of manufacturing a semiconductor structure according to embodiments of present invention. The method includes (910) forming a stack of transistors including a second transistor over a first transistor on top of a substrate, the first and the second transistor each having a first and a second source/drain (S/D) region, the first S/D region of the second transistor being on top of the first S/D region of the first transistor and the second S/D region of the second transistor being on top of the second S/D region of the first transistor; (920) creating a second opening through the first S/D region of the second transistor, the second opening exposing a top surface of the first S/D region of the first transistor; (930) forming a second silicide from the first S/D region of the second transistor at the second opening; (940) filling the second opening with a second conductive material to form a second portion of a shared S/D contact; (950) creating a first opening through the first S/D region of the first transistor, the first opening exposing a bottom cross-section of the second portion of the shared S/D contact; (960) forming a first silicide from the first S/D region of the first transistor at the first opening; and (970) filling the first opening with a first conductive material to form a first portion of the shared S/D contact, wherein the first and the second portion of the shared S/D contact are in contact with each other and together form the shared S/D contact.

Various examples may possibly be described by one or more of the following features in the following numbered clauses:

Clause 1: A semiconductor structure comprising a stack of transistors including a second transistor on top of a first transistor, the first and the second transistor cach having a first and a second source/drain (S/D) region, the first S/D region of the second transistor being on top of the first S/D region of the first transistor and the second S/D region of the second transistor being on top of the second S/D region of the first transistor; and a shared S/D contact, the shared S/D contact having a first portion being wrapped around by the first S/D region of the first transistor and a second portion being wrapped around by the first S/D region of the second transistor.

Clause 2: The semiconductor structure of clause 1, wherein the first S/D region of the first transistor includes a first type of silicide that surrounds the first portion of the shared S/D contact, and the first S/D region of the second transistor includes a second type of silicide that surrounds the second portion of the shared S/D contact, the first type of silicide being materially different from the second type of silicide.

Clause 3: The semiconductor structure of clause 2, wherein the first transistor is an n-type nanosheet transistor and the second transistor is a p-type nanosheet transistor; the first type of silicide is a titanium-silicide; and the second type of silicide is a nickel-platinum-silicide.

Clause 4: The semiconductor structure of clause 2, wherein at least a portion of a top surface of the first S/D region of the first transistor is covered by the second type of silicide.

Clause 5: The semiconductor structure of clause 1, wherein the first portion of the shared S/D contact has a top cross-section and a bottom cross-section with the top cross-section being closer to the second portion of the shared S/D contact than the bottom cross-section and having a smaller cross-sectional area than the bottom cross-section; and wherein the second portion of the shared S/D contact has a top cross-section and a bottom cross-section with the bottom cross-section being closer to the first portion of the shared S/D contact than the top cross-section and having a smaller cross-sectional area than the top cross-section.

Clause 6: The semiconductor structure of clause 5, wherein the top cross-section of the first portion of the shared S/D contact and the bottom cross-section of the second portion of the shared S/D contact have different cross-sectional shapes and sizes.

Clause 7: The semiconductor structure of clause 1, further comprising a bottom S/D contact being wrapped around by the second S/D region of the first transistor and a top S/D contact being wrapped around by the second S/D region of the second transistor, wherein the bottom S/D contact is isolated from the top S/D region by a middle-dielectric-insulator layer.

Clause 8: The semiconductor structure of clause 1, further comprising a middle-dielectric-insulator layer, the middle-dielectric-insulator layer surrounding a section of the shared S/D contact; being above the first S/D region of the first transistor; and being below the first S/D region of the second transistor.

Clause 9: The semiconductor structure of clause 1, wherein the first portion of the shared S/D contact has a first sidewall leaning inwardly, and the second portion of the shared S/D contact has a second sidewall leaning outwardly.

Clause 10: A method of forming a semiconductor structure comprising forming a stack of transistors on a substrate, the stack of transistors including a second transistor on top of a first transistor, the first and the second transistor each having a first and a second source/drain (S/D) region, the first S/D region of the second transistor being on top of the first S/D region of the first transistor and the second S/D region of the second transistor being on top of the second S/D region of the first transistor; creating a second opening through the first S/D region of the second transistor, the second opening exposing a top surface of the first S/D region of the first transistor; forming a second type of silicide from the first S/D region of the second transistor at the second opening; filling the second opening with a second conductive material to form a second portion of a shared S/D contact; creating a first opening through the first S/D region of the first transistor, the first opening exposing a bottom cross-section of the second portion of the shared S/D contact; forming a first type of silicide from the first S/D region of the first transistor at the first opening; and filling the first opening with a first conductive material to form a first portion of the shared S/D contact, wherein the first and the second portion of the shared S/D contact are in contact with each other and together form the shared S/D contact.

Clause 11: The method of clause 10, wherein creating the second opening comprises creating the second opening through a selective etch process from a frontside of the substrate resulting the second portion of the shared S/D contact having a top cross-section and a bottom cross-section with the bottom cross-section being closer to the first portion of the shared S/D contact than the top cross-section and having a smaller cross-sectional area than the top cross-section.

Clause 12: The method of clause 10, wherein creating the first opening comprises creating the first opening through a selective etch process from a backside of the substrate resulting the first portion of the shared S/D contact having a top cross-section and a bottom cross-section with the top cross-section being closer to the second portion of the shared S/D contact than the bottom cross-section and having a smaller cross-sectional area than the bottom cross-section.

Clause 13: The method of clause 10, wherein forming the second type of silicide further comprises forming the second type of silicide at the top surface of the first S/D region of the first transistor exposed by the second opening.

Clause 14: The method of clause 13, wherein creating the first opening comprises removing at least a portion of the second type of silicide formed at the top surface of the first S/D region of the first transistor to expose a bottom cross-section of the second portion of the shared S/D contact.

Clause 15: The method of clause 10, wherein creating the first opening further comprises selectively removing a placeholder underneath the first S/D region of the first transistor to expose the first S/D region of the first transistor.

Clause 16: The method of clause 10, further comprising creating a third opening through the second S/D region of the second transistor to expose a middle-dielectric-insulator layer that isolates the second S/D region of the second transistor from the second S/D region of the first transistor, and filling the third opening with a conductive material to form a top S/D contact being wrapped around by the second S/D region of the second transistor.

Clause 17: A semiconductor structure comprising a stack of transistors including a second transistor on top of a first transistor on a substrate, the first and the second transistor each having a first source/drain (S/D) region with the first S/D region of the second transistor being on top of the first S/D region of the first transistor; and a shared S/D contact, the shared S/D contact having a first portion being wrapped around by the first S/D region of the first transistor and a second portion being wrapped around by the first S/D region of the second transistor.

Clause 18: The semiconductor structure of clause 17, wherein the first transistor is an n-type transistor and the second transistor is a p-type transistor, and wherein the first S/D region of the n-type transistor includes a titanium-silicide that surrounds the first portion of the shared S/D contact, and the first S/D region of the p-type transistor includes a nickel-platinum-silicide that surrounds the second portion of the shared S/D contact.

Clause 19: The semiconductor structure of clause 18, wherein at least a portion of a top surface of the first S/D region of the n-type transistor is covered by a nickel-platinum-silicide.

Clause 20: The semiconductor structure of clause 17, wherein the first portion of the shared S/D contact has a first sidewall that leans inwardly, and the second portion of the shared S/D contact has a second sidewall that leans outwardly.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a stack of transistors including a second transistor on top of a first transistor, the first and the second transistor each having a first and a second source/drain (S/D) region, the first S/D region of the second transistor being on top of the first S/D region of the first transistor and the second S/D region of the second transistor being on top of the second S/D region of the first transistor; and
a shared S/D contact, the shared S/D contact having a first portion being wrapped around by the first S/D region of the first transistor and a second portion being wrapped around by the first S/D region of the second transistor.

2. The semiconductor structure of claim 1, wherein the first S/D region of the first transistor includes a first type of silicide that surrounds the first portion of the shared S/D contact, and the first S/D region of the second transistor includes a second type of silicide that surrounds the second portion of the shared S/D contact, the first type of silicide being materially different from the second type of silicide.

3. The semiconductor structure of claim 2, wherein the first transistor is an n-type nanosheet transistor and the second transistor is a p-type nanosheet transistor; the first type of silicide is a titanium-silicide; and the second type of silicide is a nickel-platinum-silicide.

4. The semiconductor structure of claim 2, wherein at least a portion of a top surface of the first S/D region of the first transistor is covered by the second type of silicide.

5. The semiconductor structure of claim 1, wherein the first portion of the shared S/D contact has a first top cross-section and a first bottom cross-section with the first top cross-section being closer to the second portion of the shared S/D contact than the first bottom cross-section and having a smaller cross-sectional area than the first bottom cross-section; and wherein the second portion of the shared S/D contact has a second top cross-section and a second bottom cross-section with the second bottom cross-section being closer to the first portion of the shared S/D contact than the second top cross-section and having a smaller cross-sectional area than the second top cross-section.

6. The semiconductor structure of claim 5, wherein the first top cross-section of the first portion of the shared S/D contact and the second bottom cross-section of the second portion of the shared S/D contact have different cross-sectional shapes and sizes.

7. The semiconductor structure of claim 1, further comprising a bottom S/D contact being wrapped around by the second S/D region of the first transistor and a top S/D contact being wrapped around by the second S/D region of the second transistor, wherein the bottom S/D contact is isolated from the top S/D contact by a middle-dielectric-insulator layer.

8. The semiconductor structure of claim 1, further comprising a middle-dielectric-insulator layer, the middle-dielectric-insulator layer surrounding a section of the shared S/D contact; being above the first S/D region of the first transistor; and being below the first S/D region of the second transistor.

9. The semiconductor structure of claim 1, wherein the first portion of the shared S/D contact has a first sidewall leaning inwardly, and the second portion of the shared S/D contact has a second sidewall leaning outwardly.

10. A method of forming a semiconductor structure comprising:
forming a stack of transistors on a substrate, the stack of transistors including a second transistor on top of a first transistor, the first and the second transistor each having a first and a second source/drain (S/D) region, the first S/D region of the second transistor being on top of the first S/D region of the first transistor and the second S/D region of the second transistor being on top of the second S/D region of the first transistor;
creating a second opening through the first S/D region of the second transistor, the second opening exposing a top surface of the first S/D region of the first transistor;
forming a second type of silicide from the first S/D region of the second transistor at the second opening;
filling the second opening with a second conductive material to form a second portion of a shared S/D contact;
creating a first opening through the first S/D region of the first transistor, the first opening exposing the second portion of the shared S/D contact;
forming a first type of silicide from the first S/D region of the first transistor at the first opening; and
filling the first opening with a first conductive material to form a first portion of the shared S/D contact, wherein the first and the second portion of the shared S/D contact are in contact with each other and together form the shared S/D contact.

11. The method of claim 10, wherein creating the second opening comprises creating the second opening through a selective etch process from a frontside of the substrate resulting the second portion of the shared S/D contact having a top cross-section and a bottom cross-section with the bottom cross-section being closer to the first portion of the shared S/D contact than the top cross-section and having a smaller cross-sectional area than the top cross-section.

12. The method of claim 10, wherein creating the first opening comprises creating the first opening through a selective etch process from a backside of the substrate resulting the first portion of the shared S/D contact having a top cross-section and a bottom cross-section with the top cross-section being closer to the second portion of the shared S/D contact than the bottom cross-section and having a smaller cross-sectional area than the bottom cross-section.

13. The method of claim 10, wherein forming the second type of silicide further comprises forming the second type of silicide at the top surface of the first S/D region of the first transistor exposed by the second opening.

14. The method of claim 13, wherein creating the first opening comprises removing at least a portion of the second type of silicide formed at the top surface of the first S/D region of the first transistor to expose a bottom cross-section of the second portion of the shared S/D contact.

15. The method of claim 10, wherein creating the first opening further comprises selectively removing a placeholder underneath the first S/D region of the first transistor to expose the first S/D region of the first transistor.

16. The method of claim 10, further comprising creating a third opening through the second S/D region of the second transistor to expose a middle-dielectric-insulator layer that isolates the second S/D region of the second transistor from the second S/D region of the first transistor, and filling the third opening with a conductive material to form a top S/D contact being wrapped around by the second S/D region of the second transistor.

17. A semiconductor structure comprising:
a stack of transistors including a second transistor on top of a first transistor on a substrate, the first and the second transistor each having a first source/drain (S/D) region with the first S/D region of the second transistor being on top of the first S/D region of the first transistor; and
a shared S/D contact, the shared S/D contact having a first portion being wrapped around by the first S/D region of the first transistor and a second portion being wrapped around by the first S/D region of the second transistor.

18. The semiconductor structure of claim 17, wherein the first transistor is an n-type transistor and the second transistor is a p-type transistor, and wherein the first S/D region of the first transistor includes a titanium-silicide that surrounds the first portion of the shared S/D contact, and the first S/D region of the second transistor includes a nickel-platinum-silicide that surrounds the second portion of the shared S/D contact.

19. The semiconductor structure of claim 18, wherein at least a portion of a top surface of the first S/D region of the first transistor is covered by a nickel-platinum-silicide.

20. The semiconductor structure of claim 17, wherein the first portion of the shared S/D contact has a first sidewall that leans inwardly, and the second portion of the shared S/D contact has a second sidewall that leans outwardly.
